(19) United States
(12) Patent Application Publication
(10) Pub. No.: US 2018/0366672 A1
(43) Pub. Date: Dec. 20, 2018

(54) DISPLAY PANELS OF QUANTUM-DOT LIGHT EMITTING DIODES (QLEDS) AND THE MANUFACTURING METHODS THEREOF

(71) Applicant: Wuhan China Star Optoelectronics Technology Co., Ltd., Wuhan, Hubei (CN)

(72) Inventor: Wei WANG, Shenzhen, Guangdong (CN)

(73) Assignee: Wuhan China Star Optoelectronics Technology Co., Ltd., Wuhan, Hubei (CN)

(21) Appl. No.: 15/535,701

(22) PCT Filed: Apr. 26, 2017
(86) PCT No.: PCT/CN2017/082053

§ 371 Date: Jun. 13, 2017

(30) Foreign Application Priority Data
Mar. 31, 2017 (CN) 201710209074.X

(51) Int. Cl. H01L 51/50; H01L 27/32; H01L 51/52; H01L 51/56; H01L 51/00; C09K 11/08; C09K 11/02

(52) U.S. Cl. CPC H01L 51/502; B82Y 20/00; H01L 27/3246; H01L 51/5206; H01L 51/5221; H01L 51/5056; H01L 51/5072; H01L 51/56; H01L 51/0007; H01L 51/0028; C09K 11/08; C09K 11/025; H01L 2227/323; H01L 2251/301; H01L 2251/305; H01L 2251/306; H01L 2251/308; H01L 27/3211

(57) ABSTRACT

The present disclosure relates to a QLED display panel including a TFT array substrate and a plurality of pixel structures on the TFT array substrate. The pixel structures includes a first electrode, a hole transport layer (HTL), an emissive layer (EML), an electron transport layer (ETL), and a second electrode stacked in sequence along a direction facing away the TFT array substrate. The EML comprising organic solvent material and quantum dot (QD) material dispersed in the organic solvent material, and the QD material emitting light under an electrostatically excited condition. In addition, the present disclosure also relates to a manufacturing method of QLED display panel, wherein the QD emissive layer of the pixel structures are formed by coating processes.

### BACKGROUND OF THE INVENTION

### 1. Field of the Invention

The present disclosure relates to display technology, and more particularly to a display panel of quantum-dot light emitting diodes (QLEDs) and the manufacturing method thereof, and the display device incorporating the same.

### 2. Discussion of the Related Art

OLED display devices are characterized by attributes, such as self-luminous, wide viewing angle, high luminous efficiency, low power consumption, fast response time, low temperature characteristic, simple manufacturing process and low cost. Flexible OLED display devices have brought far-reaching impact on the future of flexible OLED display device due to its advantages, including light weight, flexible, easy to carry, and so on, and will be widely adopted in the future.

The core of the OLED display device is an OLED display panel. The structure of the OLED display panel generally includes a TFT array substrate and an anode layer, a pixel definition layer, a first common layer, a light emitting layer, a second light emitting layer, a second common layer and cathode layer. The OLED display panel works by transferring the holes through the first common layer to the light emitting layer under the action of an electric field between the anode and the cathode, and the electrons are transmitted through the second common layer to the light emitting layer. The holes and the electrons within the light emitting layer are compounded so as to emit lights. OLED display panel usually adopts R, G, B three primary colors to achieve a different color display, and thus one pixel of the OLED display panel usually includes three light-emitting units. The three light-emitting units of each of the pixels can be controlled separately by the drive circuit.

As the display panel resolution increases, the number of light emitting cells per unit area is increased, resulting in a smaller distance between the light emitting units. The manufacturing method of the OLED display panel also encounters some problems. For example, generally, Fine Metal Mask (FFM) evaporation process may be adopted in the manufacturing process of the light emitting units. There are two shortcomings: (1) The utilization rate of the number of luminescent materials adopted in the evaporation process is low, which results in the high cost; (2) Current FMM evaporation process can achieve the highest resolution of 500 PPI or so. To improve the OLED pixel density, FMM vapor deposition must improve the alignment accuracy. However, due to reduced pixel pitch, the color-mixing issue may occur during the evaporation process.

### SUMMARY

The present disclosure relates to a QD-LED display panel for reducing the difficulties of the manufacturing method of the display panels and for enhancing the resolution rate of the display panel.

In one aspect, a display panel of quantum-dot light emitting diode (QLED) includes: a thin film transistor (TFT) array substrate and a plurality of pixel structures arranged in a matrix on the TFT array substrate; the pixel structures comprising a first electrode, a hole transport layer (HTL), an emissive layer (EML), an electron transport layer (ETL), and a second electrode stacked in sequence along a direction facing away the TFT array substrate; the EML comprising organic solvent material and quantum dot (QD) material dispersed in the organic solvent material, and the QD material emitting light under an electrostatically excited condition.

Wherein the pixel structure is configured as a red sub-pixel, a green sub-pixel or a blue sub-pixel, the QD emissive layer of the red sub-pixel is provided with QD material emitting red monochromatic light, the QD emissive layer of the green sub-pixel is provided with QD material emitting green monochromatic light, and the QD emissive layer of the blue sub-pixel is provided with QD material for emitting blue monochromatic light.

Wherein the pixel structure is configured as a white sub-pixel, and the QD emissive layer of the white sub-pixel is provided with QD material emitting red monochromatic light, green monochromatic light and blue monochromatic light.

Wherein the QD material may be selected from one or more of CdS, CdSe, CdTe, ZnS and ZnSe.

Wherein the second electrode is made by ITO, AZO, or FTO.

Wherein all of the second electrodes of the pixel structures are integra connected.

Wherein an inorganic thin-film protection layer is configured on the second electrode.

In another aspect, a manufacturing method of QLED display panel includes: providing a TFT array substrate, and configuring a plurality of first electrodes being arranged in a matrix on the TFT array substrate; forming a pixel defining layer on the TFT array substrate; etching a pixel defining layer by a first yellow-ray etching process to form a first-color sub-pixel area; forming at least one pixel structure within the sub-pixel area; wherein the pixel structures includes a first electrode, a hole transport layer (HTL), an emissive layer (EML), an electron transport layer (ETL), and a second electrode stacked in sequence along a direction facing away the TFT array substrate; the EML comprising organic solvent material and quantum dot (QD) material dispersed in the organic solvent material, and the QD material emitting light under an electrostatically excited condition; wherein the QD emission layer of the pixel structure is obtained by at least one coating process.

Wherein the step of forming at least one pixel structure within the sub-pixel area further includes: applying an evaporation process to the first electrode within the sub-pixel area to form the HTL; coating the HTL to form the EML; applying the evaporation process to the EML to form the ETL and the second electrode in sequence.

Wherein the method includes: S1: providing the TFT array substrate, and configuring the plurality of first electrodes being arranged in a matrix on the TFT array substrate; S2: forming a pixel defining layer on the TFT array substrate; S3: etching the pixel defining layer by a first yellow-ray etching process to form a first-color sub-pixel area; S4: forming a first-color sub-pixel structure within the first-color sub-pixel area; S5: applying a second yellow-ray etching process to form a second-color sub-pixel area on the pixel defining layer; S6: forming a second-color sub-pixel structure within the second-color sub-pixel area; S7: applying a third yellow-ray etching process to form a third-color sub-pixel area on the pixel defining layer; S8: forming the third-color sub-pixel structure within the third-color sub-pixel area.

In view of the above, the QLED display panel provided in the above embodiment adopts the QD emissive layer in the pixel structure, and utilizes the function of electroluminescence of the QD material to improve the color purity and luminous efficiency of the light emitting structure of the pixel structure. Further, in the preparation process, the QD emissive layer can be prepared by a coating process, and the emissive layer is prepared by the FMM deposition process. This not only reduces the waste of the light-emitting material, but also saves the cost. The coating process, which reduces the difficulty of the display panel process as a whole, can effectively prevent the coloration of adjacent pixels in the preparation of high-resolution display panels, and is advantageous for obtaining a higher resolution display panel.

### BRIEF DESCRIPTION OF THE DRAWINGS

FIG. 1 is a schematic view of QLED display panel in accordance with one embodiment of the present disclosure.

FIG. 2 is a schematic view of the pixel structure in accordance with one embodiment of the present disclosure.

FIG. 3 is a schematic view of the QLED display panel in accordance with another embodiment of the present disclosure.

FIG. 4 is a flowchart illustrating the manufacturing method of the QLED display panel in accordance with one embodiment of the present disclosure.

FIG. 5a-5i are schematic views of the components manufactured by the steps of the manufacturing method in FIG. 4.

FIG. 6 is a schematic view of the display device in accordance with one embodiment of the present disclosure.

### DETAILED DESCRIPTION OF THE EMBODIMENTS

Various example embodiments will now be described more fully with reference to the accompanying drawings in which some example embodiments are shown. In the drawings, the thicknesses of layers and regions may be exaggerated for clarity. In the following description, in order to avoid the known structure and/or function unnecessary detailed description of the concept of the invention result in confusion, well-known structures may be omitted and/or functions described in unnecessary detail.

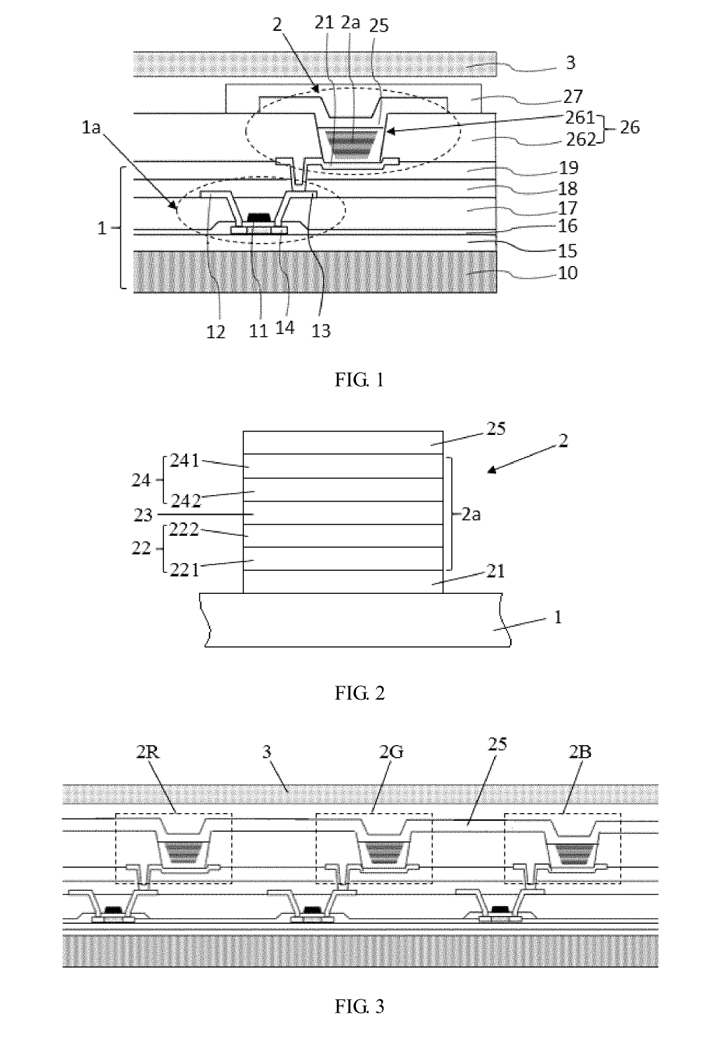

The present disclosure relates to a QLED display panel. Referring to FIGS. 1 and 2, the QLED display panel includes a thin film transistor (TFT) array substrate 1 and a plurality of pixel structures 2 arranged in a matrix on the TFT array substrate 1, wherein only one of the pixel structures 2 is taken as an example. The TFT array substrate 1 includes a plurality of TFTs 1a arranged thereon, and each of the TFTs 1a controls one pixel structure 2.

As shown in FIG. 1, the TFT array substrate 1 includes a substrate 10, and a gate 11, a source 12, a drain 13, and an active layer 14 formed on the substrate 10. The active layer 14 is formed on the substrate 10, and a buffer layer 15 is configured between the active layer 14 and the substrate 10. The active layer 14 is covered with a gate insulation layer 16. The gate 11 is arranged on the gate insulation layer 16, and the gate 11 is right above the active layer 14. The gate 11 is covered with an interlayer dielectric layer 17, the source 12 and the drain 13 are interleaved with each other and are arranged on the interlayer dielectric layer 17. In addition, the source 12 and the drain 13 electrically connect to the active layer 14 respectively via through holes on the interlayer dielectric layer 17 and the gate insulation layer 16. Further, a passivation layer 18 and a flat layer 19 are arranged on the interlayer dielectric layer 17 in sequence. In an example, the substrate 10 may be a flexible substrate so as to manufacture flexible QLED display panel, which may be adopted in wearable devices or smart/mobile device.

Referring to FIGS. 1 and 2, the pixel structure 2 includes a first electrode 21, a second electrode 25, and a light-emitting function layer 2a between the first electrode 21 and the second electrode 25. The pixel structures 2 is stacked with the first electrode 21, a hole transport layer (HTL) 22, an emissive layer (EML) 23, an electron transport layer (ETL) 24, and a second electrode 25 in sequence.

The first electrode 21 is arranged on the flat layer 19, and the first electrode 21 electrically connect to the drain 13 of the TFT 1 a respectively via the through holes on the passivation layer 18 and the flat layer 19. The first electrode 21 may be made by ITO, AZO, or FTO.

The flat layer 19 is also configured with a pixel defining layer 26 thereon. The pixel defining layer 26 covers the first electrode 21. The pixel defining layer 26 includes an opening portion 261 exposing the first electrode 21 and a spacing portion 262 for spacing apart two adjacent first electrodes 21 The light-emitting function layer is configured within the opening portion 261.

The HTL 22 includes a hole injection layer 221 and a hole transport layer 222 configured in sequence along a direction facing away the first electrode 21. The hole injection layer 221 and the hole transport layer 222 may be integrally referred to as the HTL 22.

The EML 23 includes an organic solvent material and QD material dispersed in the organic solvent material, and the QD material emits light under an electrostatically excited condition. QDs can be called as nanocrystals, which are nanoparticles consisting of Group II-VI or Group III-V elements. The particle size of the QDs is generally between 1 and 20 nm. Since the electrons and holes are quantified by the quantum confinement, the continuous band structure becomes a discrete energy level structure with molecular characteristics, which can be excited under electrosurgical conditions so as to emit fluorescence. The QD light has good fluorescence intensity and stability. The emission spectrum of the QDs can be controlled by changing the size of the QDs, and by changing the size of the QDs and its chemical composition, the emission spectrum can cover the entire visible region. Taking CdTe QDs as an example, when their particle size grows from 2.5 nm to 4.0 nm, their emission wavelengths can be shifted from 510 nm to 660 nm. In the present embodiment, the QD material may be selected from one or more of CdS, CdSe, CdTe, ZnS and ZnSe.

The ETL 24 includes an electron injection layer 241 and an electron transport layer 242 stacked in sequence along a direction facing away the second electrode 25. The electron injection layer 241 and the electron transport layer 242 may be referred to as the ETL 24.

The second electrodes 25 of each of the pixel structures 2 may be deemed as independent from each other. As shown in FIG. 3, all of the second electrodes 25 of the pixel structures 2 are integrally connected and are controlled at the same time. Thus, the first electrodes 21 of each of the pixel structures 2 are respectively controlled so as to solely control each of the pixel structures 2.

Usually, as shown in FIG. 2, in order to protect the pixel structures 2, an inorganic thin-film protection layer 27 is configured on the second electrode 25. As shown in FIG. 3, the second electrode 25 may be made by ITO, AZO, or FTO. At this moment, the second electrode 25 may function as a protection film. That is, under the circumstance, the inorganic thin-film protection layer 27 may be excluded.

The display panel is usually made by three primary colors of R, G, and B, so that the pixels of the QLED display panel provided in the above embodiment generally include R, G, and B light emitting units. The pixel structure 2 may be configured as the red sub-pixel 2R, the green sub-pixel 2G or the blue sub-pixel 2B. The red sub-pixel 2R, the green sub-pixel 2G and the blue sub-pixel 2B constitutes a pixel unit. Wherein the QD emissive layer of the red sub-pixel 2R is provided with QD material emitting red monochromatic light, the QD emissive layer of the green sub-pixel 2G is provided with QD material emitting green monochromatic light, and the QD emissive layer of the blue sub-pixel 2B is provided with QD material for emitting blue monochromatic light. In general, the three light-emitting units of R, G, and B of each pixel unit can be individually controlled by the driving circuit to realize the individual driving of each light-emitting unit.

In other examples, the pixel structure 2 is configured as a white sub-pixel. As this moment, the pixel cell not only includes the red sub-pixel 2R, the green sub-pixel 2G, and the blue sub-pixel 2B, but also includes a white sub-pixel. The QD emissive layer of the white sub-pixel is provided with QD material emitting red monochromatic light, green monochromatic light and blue monochromatic light.

Referring to FIGS. 1 and 3, the QLED display panel further includes an encapsulation structure layer 3 covering the pixel structure 2 for encapsulating the 2 for encapsulating the pixel structure 2 on the TFT array substrate 1.

The manufacturing method of the QLED display panel will be described below. First, a TFT array substrate is provided and a plurality of first electrodes are arranged in a matrix on the TFT array substrate. The pixel defining layer is manufactured on the TFT array substrate. Further, a yellow-ray etching process is applied to form the sub-pixel area on the pixel defining layer. In the end, the pixel structure is formed on the sub-pixel area, wherein the QD emissive layer of the pixel structure is obtained by coating processes.

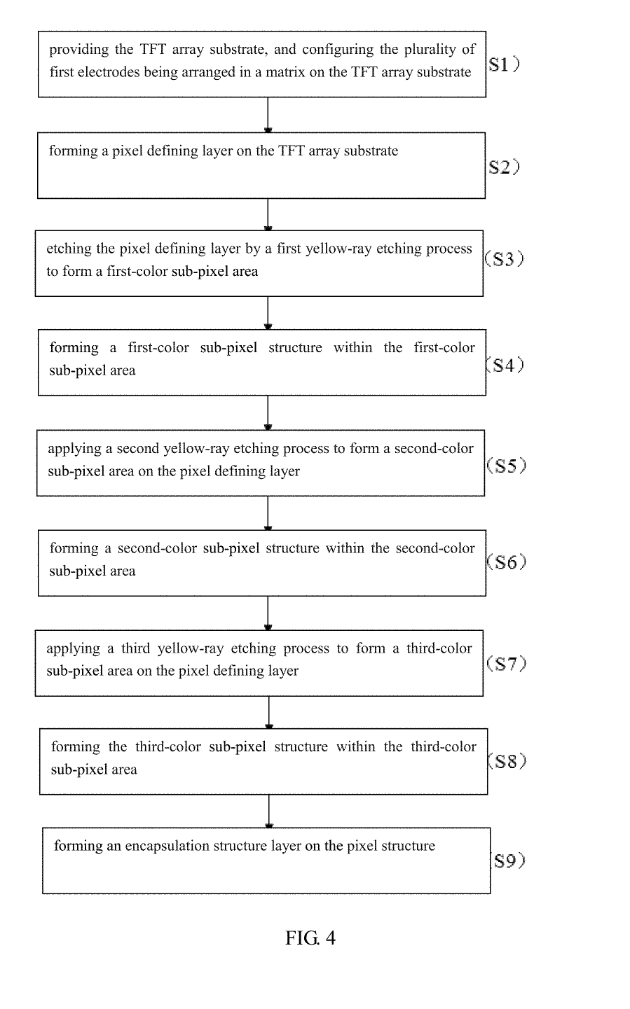

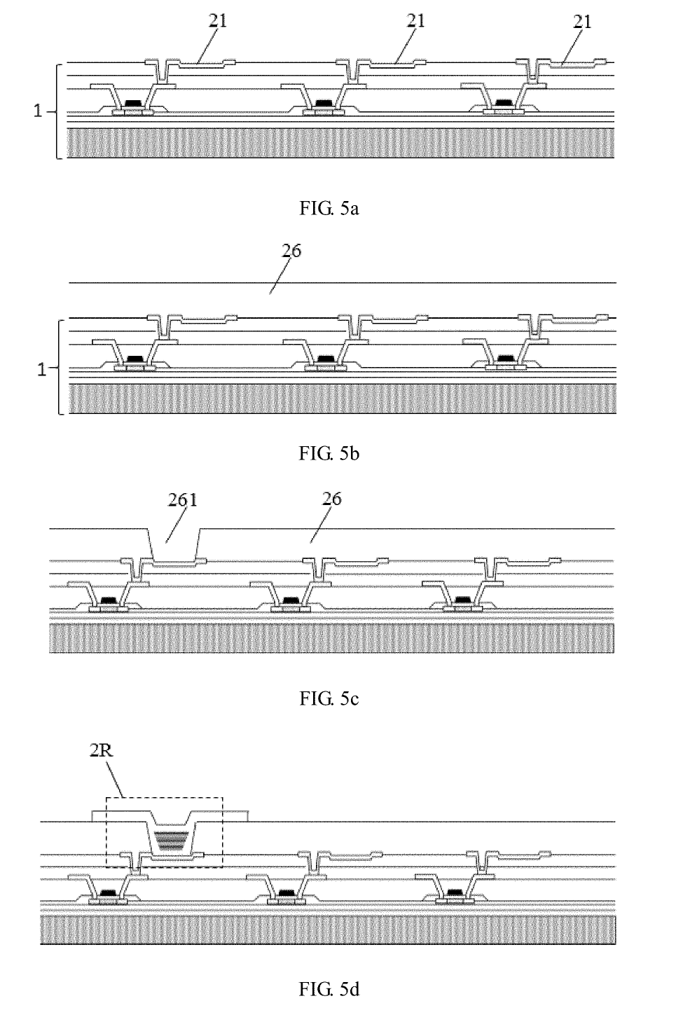

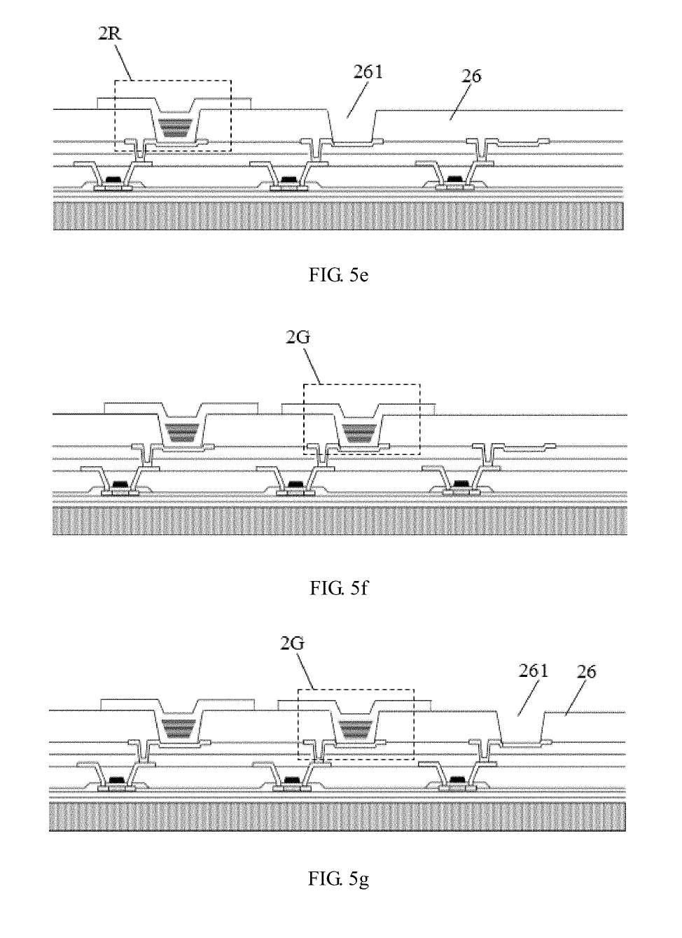

Referring to FIGS. 4, and 5a-5i, the manufacturing method of the QLED display panel includes the following steps.

In step S1, as shown in FIG. 5a, providing a TFT array substrate 1, and configuring a plurality of first electrodes 21 being arranged in a matrix on the TFT array substrate 1. The TFT array substrate 1 may be a low-temperature polycrystalline silicon (LIPS) array substrate, an oxide TFT array substrate, or a polycrystalline silicon array substrate. The first electrode 21 may be obtained by etching the metallic thin film to be the patterned first electrodes 21.

In step S2, as shown in FIG. 5b, forming a pixel defining layer 26 on the TFT array substrate 1. The pixel defining layer 26 may be formed by non-conductive organic or inorganic materials.

In step S3, as shown in FIG. 5c, etching the pixel defining layer 26 by a first yellow-ray etching process to form the first-color sub-pixel area. Specifically, the opening portion 261 is formed on the pixel defining layer 26, and the opening portion 261 corresponds to the sub-pixel area. In the embodiment, the first-color sub-pixel area is defined as the red sub-pixel.

In step S4, as shown in FIG. 5d, the first-color sub-pixel structure is formed within the first-color sub-pixel area, Which corresponds to the opening portion 261. Referring to FIG. 2, the step includes: applying an evaporation process to the first electrode 21 within the sub-pixel area to form the HTL 22. Afterward, coating the HTL 22 to form the EML 23. In the end, applying the evaporation process to the EML 23 to form the ETL 24 and the second electrode 25 in sequence. In the embodiment, the QD material may emit red mono-color rays to obtain the red sub-pixel 2R. In the manufacturing process of the EML 23, the QD material are dispersed within the organic solution to form a pre-driving mixed solution. Afterward, the slit coating or spin coating are adopted to coat the pre-driving mixed solution on the HTL 22. Further, a baking or an annealing process is applied to obtain the EML 23.

In step S5, as shown in FIG. 5e, applying a second yellow-ray etching process to form the second-color sub-pixel area on the pixel defining layer 26. In the embodiment, the second-color sub-pixel area is configured as the green sub-pixel. It is to be noted that the second etching process is conducted after the first-color sub-pixel structure is formed. The first-color sub-pixel structure is prevented from being damaged due to the protection layer thereon. In one embodiment, the second electrode 25 may be made by ITO, AZO, or FTO, which may function as the protection film, and thus additional inorganic thin film protection layer may be excluded.

In step S6, as shown in FIG. 5f, the second-color sub-pixel structure is formed within the second-color sub-pixel area. In the embodiment, the QD material may emit green mono-color rays to obtain the red sub-pixel 2G The detail step may be conducted as step S4.

In step S7, as shown in FIG. 5g, applying a third yellow-ray etching process to form the third-color sub-pixel area on the pixel defining layer 26. In the embodiment, the third-color sub-pixel area is configured as the blue sub-pixel.

In step S8, as shown in FIG. 5h, the third-color sub-pixel structure is formed within the third-color sub-pixel area. In the embodiment, the QD material may emit blue mono-color rays to obtain the red sub-pixel 2B. The detail step may be conducted as step S4.

In step S9, as shown in FIG 5i, forming an encapsulation structure layer 3 on the pixel structure 2.

As stated above, the pixel electrodes of different colors are formed in sequence. That is, the red sub-pixel, the green sub-pixel, and the blue sub-pixel are formed in sequence. It can be understood that the sequence of the three colors may be exchanged.

In view of the above, the QLED display panel provided in the above embodiment adopts the QD emissive layer in the pixel structure, and utilizes the function of electroluminescence of the QD material to improve the color purity and luminous efficiency of the light emitting structure of the pixel structure. Further, in the preparation process, the QD emissive layer can be prepared by a coating process, and the emissive layer is prepared by the FMM deposition process. This not only reduces the waste of the light-emitting material, but also saves the cost. The coating process, which reduces the difficulty of the display panel process as a whole, can effectively prevent the coloration of adjacent pixels in the preparation of high-resolution display panels, and is advantageous for obtaining a higher resolution display panel.

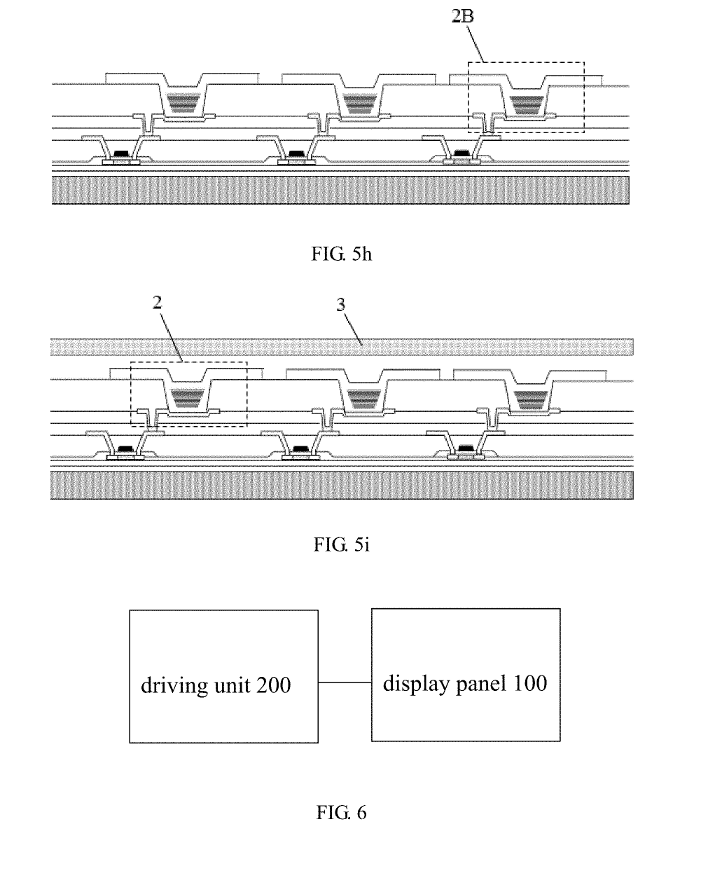

The present disclosure also relates to a display device. As shown in FIG. 6, the display device includes a driving unit 200 and a display panel 100. The driving unit 200 provides driving signals to the display panel 100 such that the display panel 100 can display images. The display panel 100 adopts the above QLED display panel.

It should be noted that the relational terms herein, such as “first” and “second”, are used only for differentiating one entity or operation, from another entity or operation, which, however do not necessarily require or imply that there should be any real relationship or sequence. Moreover, the terms “comprise”, “include” or any other variations thereof are meant to cover non-exclusive including, so that the process, method, article or device comprising a series of elements do not only comprise those elements, but also comprise other elements that are not explicitly listed or also comprise the inherent elements of the process, method, article or device. In the case that there are no more restrictions, an element qualified by the statement “comprises a . . . ” does not exclude the presence of additional identical elements in the process, method, article or device that comprises the said element.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A display panel of quantum-dot light emitting diode (QLED), comprising:
a thin film transistor (TFT) array substrate and a plurality of pixel structures arranged in a matrix on the TFT array substrate;
the pixel structures comprising a first electrode, a hole transport layer (HTL), an emissive layer (EML), an electron transport layer (ETL), and a second electrode stacked in sequence along a direction facing away the TFT array substrate;
the EML comprising organic solvent material and quantum dot (QD) material dispersed in the organic solvent material, and the QD material emitting light under an electrostatically excited condition.

2. The QLED display panel as claimed in claim 1, wherein the pixel structure is configured as a red sub-pixel, a green sub-pixel or a blue sub-pixel, the QD emissive layer of the red sub-pixel is provided with QD material emitting red monochromatic light, the QD emissive layer of the green sub-pixel is provided with QD material emitting green monochromatic light, and the QD emissive layer of the blue sub-pixel is provided with QD material for emitting blue monochromatic light.

3. The QLED display panel as claimed in claim 2, wherein the pixel structure is configured as a white sub-pixel, and the QD emissive layer of the white sub-pixel is provided with QD material emitting red monochromatic light, green monochromatic light and blue monochromatic light.

4. The QLED display panel as claimed in claim 1, wherein the QD material may be selected from one or more of CdS, CdSe, CdTe, ZnS and ZnSe.

5. The QLED display panel as claimed in claim 1, wherein the second electrode is made by ITO, AZO, or FTO.

6. The QLED display panel as claimed in claim 1, wherein all of the second electrodes of the pixel structures are integrally connected.

7. The QLED display panel as claimed in claim 1, wherein an inorganic thin-film protection layer is configured on the second electrode.

8. A manufacturing method of QLED display panel, comprising:
providing a TFT array substrate, and configuring a plurality of first electrodes being arranged in a matrix on the TFT array substrate;
forming a pixel defining layer on the TFT array substrate;
etching a pixel defining layer by a first yellow-rayetching process to form a first-color sub-pixel area;
forming at least one pixel structure within the sub-pixel area;
wherein the pixel structures comprises a first electrode, a hole transport layer (HTL), an emissive layer (EML) an electron transport layer (ETL), and a second electrode stacked in sequence along a direction facing away the TFT array substrate;
the EML comprising organic solvent material and quantum dot (QD) material dispersed in the organic solvent material, and the QD material emitting light under an electrostatically excited condition;
wherein the QD emission layer of the pixel structure is obtained by at least one coating process.

9. The manufacturing method as claimed in claim 8, wherein the step of forming at least one pixel structure within the sub-pixel area further comprises:
applying an evaporation process to the first electrode within the sub-pixel area to form the HTL;
coating the HTL to form the EML;
applying the evaporation process to the EML to form the ETL and the second electrode in sequence.

10. The manufacturing method as claimed in claim 9, wherein the method comprises:
S1: providing the TFT array substrate, and configuring the plurality of first electrodes being arranged in a matrix on the TFT array substrate;
S2: forming a pixel defining layer on the TFT array substrate;
S3: etching the pixel defining layer by a first yellow-ray etching process to form a first-color sub-pixel area;
S4: forming a first-color sub-pixel structure within the first-color sub-pixel area;
S5: applying a second yellow-ray etching process to form a second-color sub-pixel area on the pixel defining layer;
S6: forming a second-color sub-pixel structure within the second-color sub-pixel area;
S7: applying a third yellow-ray etching process to form a third-color sub-pixel area on the pixel defining layer;
S8: forming the third-color sub-pixel structure within the third-color sub-pixel area.

11. The manufacturing method as claimed in claim 9, wherein the QD material may be selected from one or more of CdS, CdSe, CdTe, ZnS and ZnSe.

12. The manufacturing method as claimed in claim 9, wherein the second electrode is made by ITO, AZO, or FTO.

13. The manufacturing method as claimed in claim 9, wherein all of the second electrodes of the pixel structures are integrally connected.

14. A display device, comprising:
a driving unit and a display panel;
the driving unit providing driving signals to the display panel such that the display panel displays images; wherein the display panel is QLED display panel comprising:
a TFT array substrate and a plurality of pixel structures arranged in a matrix on the TFT array substrate;
the pixel structures comprising a first electrode, a hole transport layer (HTL), an emissive layer (EML), an electron transport layer (ETL), and a second electrode stacked in sequence along a direction facing away the TFT array substrate;
the EML comprising organic solvent material and quantum dot (QD) material dispersed in the organic solvent material, and the QD material emitting light under an electrostatically excited condition.

15. The display device as claimed in claim 14, wherein the pixel structure is configured as a red sub-pixel, a green sub-pixel or a blue sub-pixel, the QD emissive layer of the red sub-pixel is provided with QD material emitting red monochromatic light, the QD emissive layer of the green sub-pixel is provided with QD material emitting green monochromatic light, and the QD emissive layer of the blue sub-pixel is provided with QD material for emitting blue monochromatic light.

16. The display device as claimed in claim 15, wherein the pixel structure is configured as a white sub-pixel, and the QD emissive layer of the white sub-pixel is provided with QD material emitting red monochromatic light, green monochromatic light and blue monochromatic light.

17. The display device as claimed in claim 14, wherein the QD material may be selected from one or more of CdS, CdSe, CdTe, ZnS and ZnSe.

18. The display device as claimed in claim 14, wherein the second electrode is made by ITO, AZO, or FTO.

19. The display device as claimed in claim 14, wherein all of the second electrodes of the pixel structures are integrally connected.

20. The display device as claimed in claim 14, wherein an inorganic thin-film protection layer is configured on the second electrode.
